(19) United States
(12) Patent Application Publication
(10) Pub. No.: US 2021/0013375 A1
(43) Pub. Date: Jan. 14, 2021

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventor: Mei-Yi WU, Kaohsiung (TW)

(73) Assignee: Advanced Semiconductor Engineering, Inc., Kaohsiung (TW)

(21) Appl. No.: 16/509,397

(22) Filed: Jul. 11, 2019

(51) Int. Cl. H01L 33/48; H01L 23/00; H01L 33/62

(52) U.S. Cl. CPC H01L 33/483; H01L 33/62; H01L 24/28

(57) ABSTRACT

A semiconductor device package includes a carrier, a conductive pillar, an adhesive layer and a package body. The conductive pillar is disposed on the carrier. The conductive pillar has a top surface facing away from the carrier. The adhesive layer is disposed on the top surface of the conductive pillar. The package body is disposed on the carrier. The package body has a top surface facing away from the carrier. The top surface has a first portion and a second portion. The first portion and the second portion of the top surface of the package body are discontinuous.

### BACKGROUND

### 1. Technical Field

The present disclosure relates to a semiconductor device package, and more particularly, to a semiconductor device package including a trench.

### 2. Description of the Related Art

In a semiconductor device package (e.g., an optical device), a die or chip (e.g., a light emitting device) is disposed on a carrier and a lid is attached to the carrier to cover the die. The lid may be electrically connected to the carrier through conductive pillars. The conductive pillars are attached to the transparent lid through a conductive glue or tape. However, during the manufacturing process, voids may exist in the conductive glue or tape, which may adversely affect the electrical performance of the semiconductor device package, even causing a failure of the semiconductor device package.

### SUMMARY

In some embodiments, a semiconductor device package includes a carrier, a conductive pillar, an adhesive layer and a package body. The conductive pillar is disposed on the carrier. The conductive pillar has a top surface facing away from the carrier. The adhesive layer is disposed on the top surface of the conductive pillar. The package body is disposed on the carrier. The package body has a top surface facing away from the carrier. The top surface has a first portion and a second portion. The first portion and the second portion of the top surface of the package body are discontinuous.

In some embodiments, a semiconductor device package includes a carrier, a conductive pillar, a package body, and an adhesive layer. The conductive pillar disposed on the carrier. The conductive pillar having a top surface facing away from the carrier. The package body is disposed on the carrier. The package body defines a cavity to expose a portion of the carrier and a trench connected to the cavity. The adhesive layer is disposed on the top surface of the conductive pillar. At least a portion of a sidewall of the adhesive layer is exposed from the trench of the package body.

In some embodiments, a semiconductor device package includes a carrier, a conductive pillar, a package body and an adhesive layer. The conductive pillar is disposed on the carrier. The conductive pillar has a top surface facing away from the carrier. The package body is disposed on the carrier. The package body defines a cavity to expose a portion of the carrier, a first trench connected to the cavity and a second trench connected to the external of the semiconductor device package. The adhesive layer is disposed on the top surface of the conductive pillar and between the first trench and the second trench.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of a semiconductor device package in accordance with some embodiments of the present disclosure.

FIG. 1B illustrates a top view of a semiconductor device package in accordance with some embodiments of the present disclosure.

FIG. 2A illustrates a cross-sectional view of a semiconductor device package in accordance with some embodiments of the present disclosure.

FIG. 2B illustrates a top view of a semiconductor device package in accordance with some embodiments of the present disclosure.

FIG. 2C illustrates a top view of a semiconductor device package in accordance with some embodiments of the present disclosure.

FIG. 3 illustrates a cross-sectional view of a semiconductor device package in accordance with some embodiments of the present disclosure.

FIG. 4 illustrates a cross-sectional view of a semiconductor device package in accordance with some embodiments of the present disclosure.

Common reference numerals are used throughout the drawings and the detailed description to indicate the same or similar components. The present disclosure can be best understood from the following detailed description taken in conjunction with the accompanying drawings.

### DETAILED DESCRIPTION

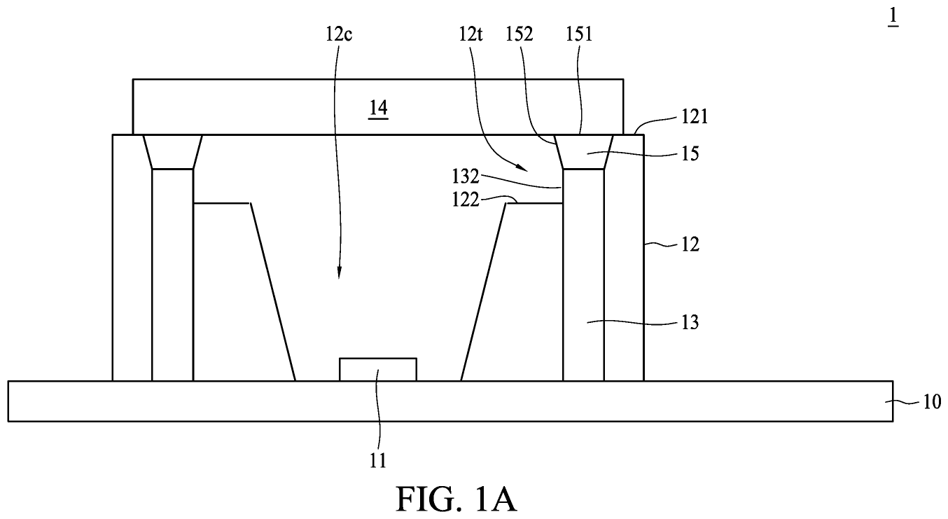

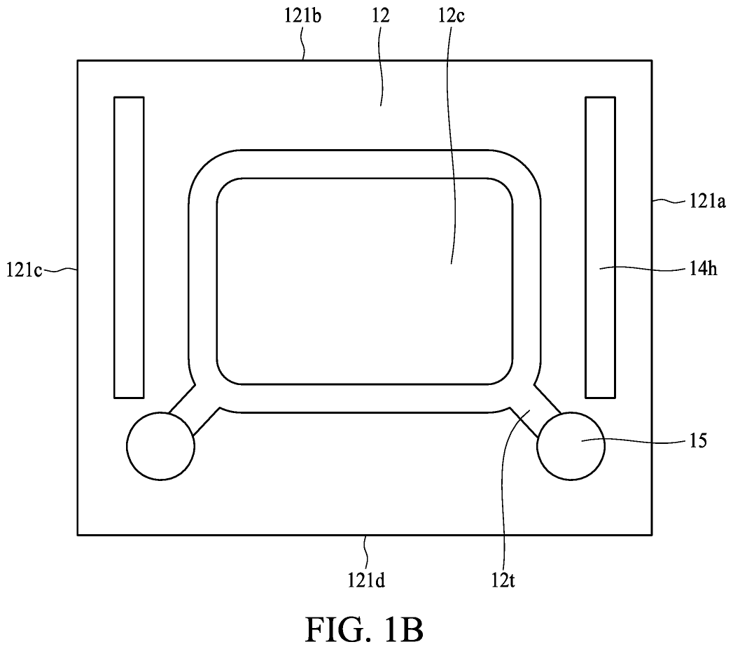

FIG. 1A illustrates a cross-sectional view of a semiconductor device package 1 in accordance with some embodiments of the present disclosure. The semiconductor device package 1 includes 1 carrier 10, an electronic component 11, a package body 12, a conductive pillar 13, a lid 14 and an adhesive layer 15. In some embodiments, the semiconductor device package may be or includes an optical device. In other embodiments, the semiconductor device package may be any other electronic devices other than an optical device.

The carrier 10 may include, for example, a printed circuit board, such as a paper-based copper foil laminate, a composite copper foil laminate, or a polymer-impregnated glass-fiber-based copper foil laminate. The carrier 10 may include an interconnection structure, such as a plurality of conductive traces or a through via. In some embodiments, the carrier 10 includes a ceramic material or a metal plate. In some embodiments, the carrier 10 may include a substrate, such as an organic substrate or a leadframe. In some embodiments, the carrier 10 may include a two-layer substrate which includes a core layer and a conductive material and/or structure disposed on an upper surface and a bottom surface of the carrier 10. The conductive material and/or structure may include a plurality of traces.

The electronic component 11 is disposed on the carrier 10. The electronic component 11 may include an emitting die or other optical die. For example, the electronic component 11 may include a light-emitting diode (LED), a laser diode, a vertical-cavity surface-emitting laser (VCSEL) or another device that may include one or more semiconductor layers. The semiconductor layers may include silicon, silicon carbide, gallium nitride, or any other semiconductor materials. The electronic component 11 can be connected to the carrier 10 by way of flip-chip or wire-bond techniques, for example. In some embodiments, the electronic component 11 includes an LED die bonded on the carrier 10 via a die bonding material. The LED die includes at least one wire-bonding pad. The LED die is electrically connected to the carrier 10 by a conductive wire, one end of which is bonded to the wire-bonding pad of the LED die and another end of which is bonded to a wire-bonding pad of the carrier 10. The electronic component 11 has an active region (or light emitting area) facing toward the lid 14. In other embodiments, the electronic component 11 may include a light detector or sensor (e.g., a PIN diode, a photo-diode, a photo-transistor or the like). In some embodiments, the electronic component may include any semiconductor dies or chips other than optical components.

The conductive pillar (e.g., copper pillar or copper post) 13 is disposed on the carrier 10. The conductive pillar 13 is disposed between the carrier 10 and the lid 14 and electrically connects the lid 14 with the carrier 10. The conductive pillar 13 is attached or bonded to the lid 14 through the adhesive layer 15. In some embodiments, the adhesive layer 15 includes a conducting material, such as sliver paste, solder paste or the like. The conductive pillar 13 may be a solid cylindrical post, a solid square post, or a solid post with a suitable shape. In some embodiments, the number of the conductive pillar 13 can be changed depending on different design specifications.

The lid 14 is disposed on the adhesive layer 15 and the package body 12. For example, the lid 14 is disposed on a coplanar surface defined by a surface 151 of the adhesive layer 15 and a surface 121 of the package body 12. The lid 14 includes a patterned conductive layer (or a conductive trace). The patterned conductive layer is disposed on a lower surface of the lid 14 (e.g. facing the carrier 10). The patterned conductive layer may be embedded in and exposed by the lower surface of the lid 14. The patterned conductive layer is electrically connected to the carrier 10 via the conductive pillar 13 and the adhesive layer 15. The lid 14 may include a transparent material. The lid 14 may include a conductive material or a dielectric material. In some embodiments, the lid 14 may include a glass, a transparent metal (e.g. an indium-tin-oxide (ITO) or an indium-zinc-oxide (IZO)), or a plastic. In some embodiments, the lid 14 may be a shield (e.g., an electromagnetic interference (EMI) shield) configured to prevent the electronic component 11 from being interfered by electromagnetic radiation/wave from the outside of the semiconductor device package 1.

In some embodiments, the lid 14 is also attached or bonded to the package body 12 through an adhesive layer. For example, as shown in FIG. 1B, which illustrates a top view of the semiconductor device package 1 in FIG. 1A (for clarity, some of the components (such as the lid 14, the carrier 10 and the electronic component 11) are omitted in FIG. 1B), an adhesive layer 14h is disposed on the surface 121 of the package body 12. The adhesive layer 14h may be disposed adjacent to edges of the surface 121 of the package body 12. In some embodiments, as shown in FIG. 1B, the adhesive layer 14h is disposed adjacent to the edges 121a and 121c of the surface 121 of the package body 12. Since no adhesive layer is disposed adjacent to the edges 121b and 121d of the surface 121 of the package body 12, gaps between the lid 14 and the surface 121 of the package body 12 may be defined adjacent to the edges 121b and 121d. The gaps may act as vent holes to allow the air within the cavity 12c defined by the package body 12 to flow to the outside of the cavity 12c, which can avoid the popcorn effect during the manufacturing process.

The package body (or encapsulant) 12 is disposed on the carrier 10. The package body 12 defines a cavity 12c to accommodate the electronic component 11. The package body 12 covers a portion of the conductive pillar 13 and a portion of the adhesive layer 15. The package body 12 also defines a trench (or trenches) 12t to expose a portion of a sidewall 132 of the conductive pillar 13 and a portion of a sidewall 152 of the adhesive layer 15. As shown in FIG. 1A, the package body 12 has a surface 122 lower than the surface 121 of the package body 12. For example, the surfaces 121 and 122 of the package body 12 are discontinuous. For example, a distance between the surface 122 of the package body 12 and the carrier is less than a distance between the surface 121 of the package body 12. In some embodiments, the surface 122 of the package body 12 is lower than an interface of the conductive pillar 13 and the adhesive layer 15. The trench 12t may be formed by laser, etching or any other suitable processes. In some embodiments, a roughness of the surface 122 of the package body 12 is greater than a roughness of the surface 121 of the package body 12. In some embodiments, before the adhesive layer 15 has been cured, the adhesive layer 15 may has fluidity, and hence a portion of the adhesive layer 15 may be disposed on a portion of the sidewall 132 of the conductive pillar 13 and/or the surface 122 of the package body 12. In some embodiments, the package body 12 includes an epoxy resin having fillers, a molding compound (e.g., an epoxy molding compound or other molding compound), a polyimide, a phenolic compound or material, a material with a silicone dispersed therein, or a combination thereof.

During some of the process (e.g., reflow, cure or the like) for manufacturing a semiconductor device package, voids may be generated in the adhesive layer (or adjacent to an interface between the adhesive layer and the conductive pillar), which would adversely affect the electrical performance of the semiconductor device package, even causing a failure of the semiconductor device package. In some embodiments, the above issues may be mitigated by low-temperature multi-stage baking the adhesive layer and the conductive pillar. However, this can eliminate the voids adjacent to the center of the adhesive layer, but the voids adjacent to the periphery of the adhesive layer cannot be fully eliminated. In addition, the low-temperature multi-stage baking operation would increase the manufacturing cost and time. In accordance with the embodiments in FIGS. 1A and 1B, the voids adjacent to either the center or the periphery of the adhesive layer 15 can be fully vented through the trench 12t. In some embodiments, there is no void in the adhesive layer 15 or adjacent to an interface between the adhesive layer 15 and the conductive pillar 13 under the curing operation for more than 8 hours. This can strengthen the connection between the adhesive layer 15 and the conductive pillar 13 and enhance the performance of the semiconductor device package 1.

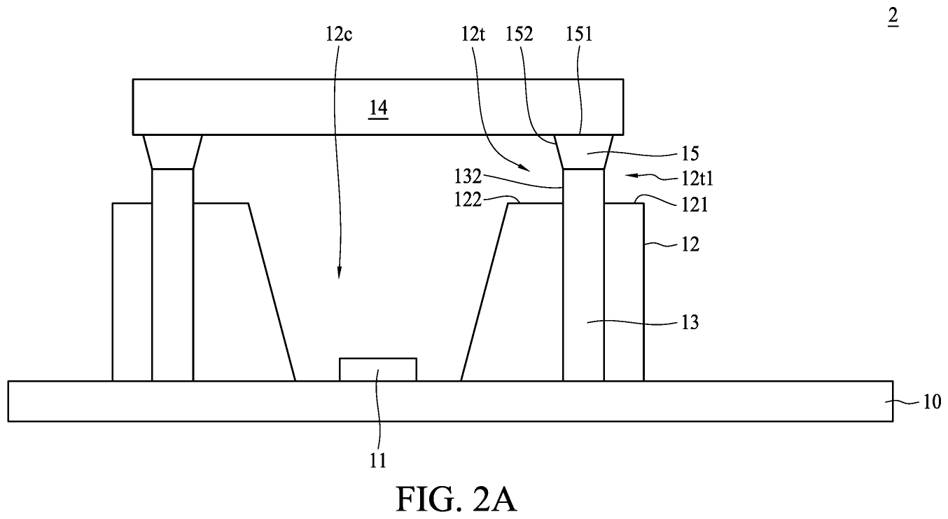

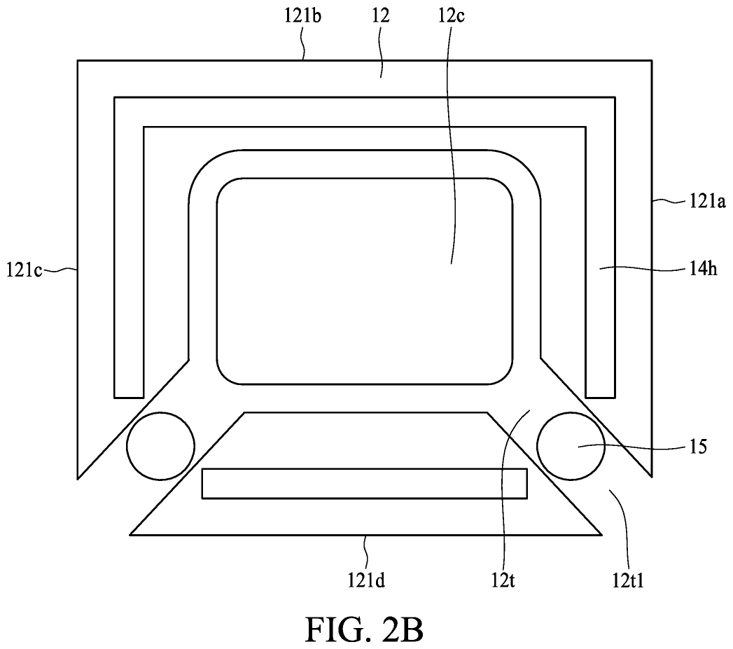

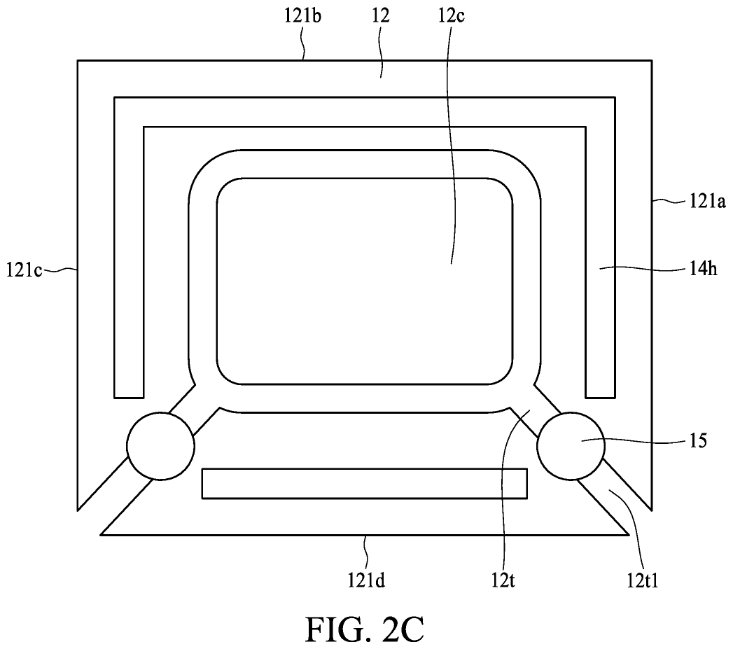

FIG. 2A illustrates a cross-sectional view of a semiconductor device package 2 in accordance with some embodiments of the present disclosure. FIG. 2B illustrates a top view of the semiconductor device package 2 in FIG. 2A in accordance with some embodiments of the present disclosure (for clarity, some of the components (such as the lid 14, the carrier 10 and the electronic component 11) are omitted in FIG. 2B). The semiconductor device package 2 in FIGS. 2A and 2B is similar to the semiconductor device package 1 in FIGS. 1A and 1B, except that the package body 12 of the semiconductor device package 2 further defines a trench 12t1 in addition to the trench 12t. The trench 12t and the trench 12t1 are connected to vent both the voids in the adhesive layer 15 (or adjacent to an interface between the adhesive layer 15 and the conductive pillar 13) and the air within the cavity 12c. Hence, no additional gap between the surface 121 of the package body 12 and the lid 14 is included. For example, as shown in FIG. 2B, the adhesive layer 14h are disposed adjacent to all the edges 121a, 121b, 121c and 121d of the surface 121 of the package body 12. This can enhance the sealing capability of the semiconductor device package 2 to prevent water and particles from entering the cavity 12c.

FIG. 2C illustrates a top view of the semiconductor device package 2 in FIG. 2A in accordance with some embodiments of the present disclosure (for clarity, some of the components (such as the lid 14, the carrier 10 and the electronic component 11) are omitted in FIG. 2C). The structure illustrated in FIG. 2C is similar to that in FIG. 2B, except that in FIG. 2B, a width of the trenches 12t and 12t1 is greater than a width of the adhesive layer 15 while in FIG. 2C, the width of the trenches 12t and 12t1 is less than the width of the adhesive layer 15. In some embodiments, the width of the trenches 12t and 12t1 can be the same as the width of the adhesive layer 15. In some embodiments, the shape and the size of the trench 12t (or 12t1) can be adjusted or changed depending on different design specifications.

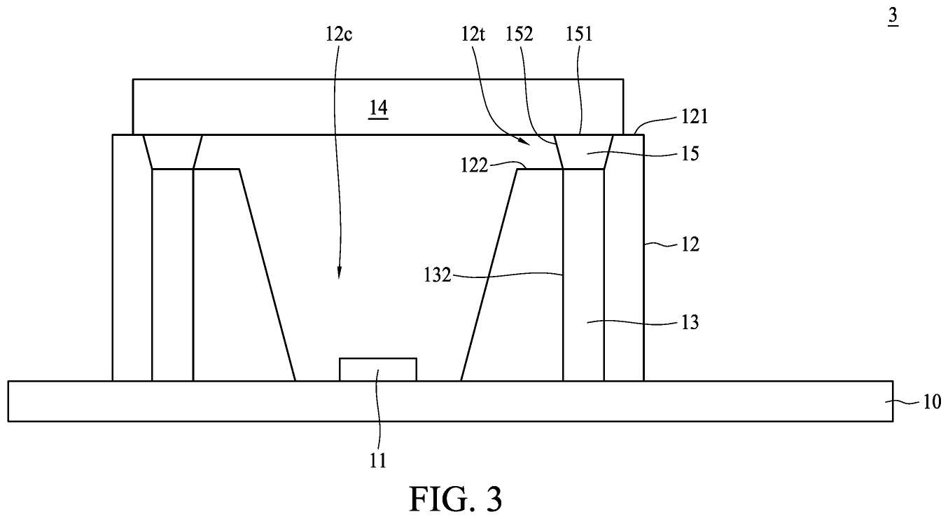

FIG. 3 illustrates a cross-sectional view of a semiconductor device package 3 in accordance with some embodiments of the present disclosure. The semiconductor device package 3 is similar to the semiconductor device package 1 in FIG. 1A, except that in FIG. 3, the surface 122 of the package body 12 is substantially coplanar with the interface between the adhesive layer 15 and the conductive pillar 13. For example, the surface 122 of the package body 12 is substantially coplanar with an upper surface of the conductive pillar 13. For example, the sidewall 132 of the conductive pillar 13 is fully covered by the package body 12, while the sidewall 151 of the adhesive layer 15 is fully exposed from the package body 12.

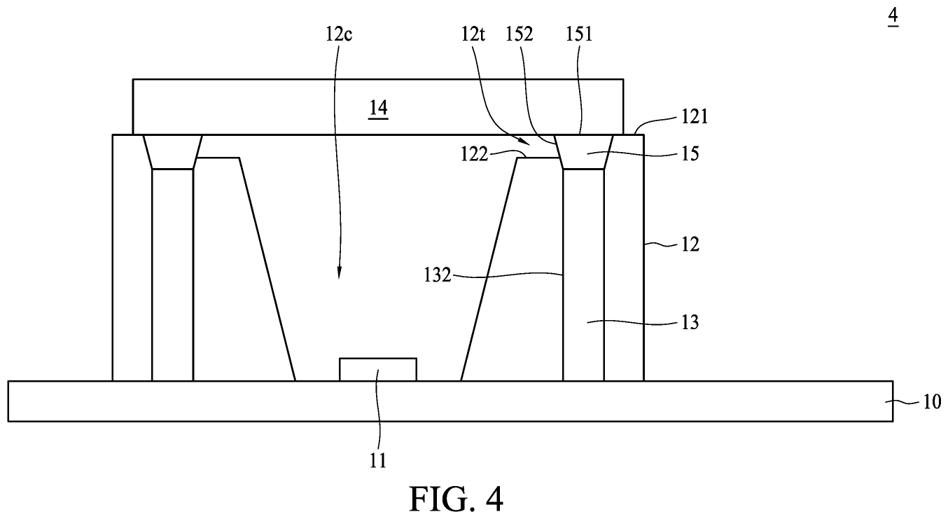

FIG. 4 illustrates a cross-sectional view of a semiconductor device package 4 in accordance with some embodiments of the present disclosure. The semiconductor device package 4 is similar to the semiconductor device package 1 in FIG. 1A, except that in FIG. 4, the surface 122 of the package body 12 is higher than the interface between the adhesive layer 15 and the conductive pillar 13. For example, the surface 122 of the package body 12 is higher than an upper surface of the conductive pillar 13. For example, the sidewall 132 of the conductive pillar 13 is fully covered by the package body 12, a portion of the sidewall 151 of the adhesive layer 15 is covered by the package body 12, and the other portion of the sidewall 151 of the adhesive layer 15 is exposed from the package body 12.

In the description of some embodiments, a component provided “on” another component can encompass cases where the former component is directly on (e.g., in physical contact with) the latter component, as well as cases where one or more intervening components are located between the former component and the latter component.

In the description of some embodiments, a component characterized as “light transmitting” or “transparent” can refer to such a component as having a light transmittance of at least 80%, such as at least 85% or at least 90%, over a relevant wavelength or a relevant range of wavelengths, such as a peak infrared wavelength or a range of infrared wavelengths emitted by a light emitter. In the description of some embodiments, a component characterized as “light shielding,” “light blocking,” or “opaque” can refer to such a component as having a light transmittance of no greater than 20%, such as no greater than 15% or no greater than 10%, over a relevant wavelength or a relevant range of wavelengths, such as a peak infrared wavelength or a range of infrared wavelengths emitted by a light emitter.

Additionally, amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

While the present disclosure has been described and illustrated with reference to specific embodiments thereof, these descriptions and illustrations do not limit the present disclosure. It will be clearly understood by those skilled in the art that various changes may be made, and equivalents may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it should be understood that these operations may be combined, sub-divided, or re-ordered to form an equivalent method without departing from the teachings of the present disclosure. Therefore, unless specifically indicated herein, the order and grouping of the operations are not limitations of the present disclosure.

1. A semiconductor device package comprising:
a carrier;
a conductive pillar disposed on the carrier, the conductive pillar having a top surface facing away from the carrier;
an adhesive layer disposed on the top surface of the conductive pillar; and
a package body disposed on the carrier, the package body having a top surface facing away from the carrier, the top surface having a first portion and a second portion,
wherein the first portion and the second portion of the top surface of the package body are discontinuous and at different elevations, and the adhesive layer is spaced apart from the second portion of the top surface of the package body.

2. The semiconductor device package of claim 1, wherein a distance between the first portion of the top surface of the package body and the carrier is greater than a distance between the second portion of the top surface of the package body and the carrier.

3. The semiconductor device package of claim 1, wherein the first portion of the top surface of the package body is substantially coplanar with a top surface of the adhesive layer.

4. The semiconductor device package of claim 1, wherein a distance between the second portion of the top surface of the package body and the carrier is less than a distance between the top surface of the conductive pillar and the carrier.

5. The semiconductor device package of claim 1, wherein a width of the second portion of the top surface of the package body is greater than a width of the adhesive layer.

6. The semiconductor device package of claim 1, wherein a roughness of the second portion of the top surface of the package body is greater than a roughness of the first portion of the top surface of the package body.

7. The semiconductor device package of claim 1, further comprising a light emitting device disposed on the carrier, wherein the package body defines a cavity to accommodate the light emitting device.

8. The semiconductor device package of claim 1, wherein the adhesive layer comprises conductive paste.

9. A semiconductor device package comprising:
a carrier;
a conductive pillar disposed on the carrier, the conductive pillar having a top surface facing away from the carrier;
a package body disposed on the carrier, the package body defining a cavity to expose a portion of the carrier and a trench connected to the cavity; and
an adhesive layer disposed on the top surface of the conductive pillar,
wherein at least a portion of a sidewall of the adhesive layer is exposed from the trench of the package body, and the trench is defined by a portion of the top surface of the package body and a first sidewall of the conductive pillar.

10. The semiconductor device package of claim 9, wherein the adhesive layer has a first sidewall facing the cavity and a second sidewall facing away from the cavity, and the first sidewall of the adhesive layer is exposed from the trench of the package body.

11. The semiconductor device package of claim 10, wherein the second sidewall of the adhesive layer is covered by the package body.

12. The semiconductor device package of claim 9, wherein
the conductive pillar has the first sidewall facing the cavity and a second sidewall facing away from the cavity;
a portion of the first sidewall is exposed from the trench of the package body; and
the second sidewall is covered by the package body.

13. The semiconductor device package of claim 9, wherein a width of the trench of the package body is less than, equal to a width of the adhesive layer.

14. The semiconductor device package of claim 9, further comprising a transparent conductive lid disposed on the adhesive layer and the package body.

15. The semiconductor device package of claim 14, wherein the transparent conductive lid is electrically connected to the carrier through the adhesive layer and the conductive pillar.

16. The semiconductor device package of claim 9, further comprising a light emitting device disposed on the carrier and within the cavity of the package body.

17. The semiconductor device package of claim 9, wherein the adhesive layer comprises silver paste.

18. A semiconductor device package comprising:
a carrier;
a conductive pillar disposed on the carrier, the conductive pillar having a top surface facing away from the carrier;
a package body disposed on the carrier, the package body defining a cavity to expose a portion of the carrier, a first trench connected to the cavity and a second trench connected to the external of the semiconductor device package; and
an adhesive layer disposed on the top surface of the conductive pillar and between the first trench and the second trench, wherein the first trench and the second trench comprise vent holes, and a portion of the conductive pillar is exposed from the first trench and the second trench.

19. The semiconductor device package of claim 18, wherein the adhesive layer includes solder paste.

20. The semiconductor device package of claim 18, wherein the first trench is connected to the second trench.
